(19) United States
(12) Patent Application Publication
(10) Pub. No.: US 2013/0118044 A1
(43) Pub. Date: May 16, 2013

(54) SYSTEM TO DISPLAY A FLAG AND METHOD TO MANUFACTURE THE SYSTEM

(71) Applicants: Anthony Scaturro, Tampa, FL (US); Paul Donohue, North Wales, PA (US); Randy Mepplelink, Holland, MI (US); David Daugherty, Zeeland, MI (US)

(72) Inventors: Anthony Scaturro, Tampa, FL (US); Paul Donohue, North Wales, PA (US); Randy Mepplelink, Holland, MI (US); David Daugherty, Zeeland, MI (US)

(21) Appl. No.: 13/647,535

(22) Filed: Oct. 9, 2012

Related U.S. Application Data
(60) Provisional application No. 61/560,027, filed on Nov. 15, 2011.

(51) Int. Cl. G09F 11/18; H05K 13/04; B23P 11/00

(52) U.S. Cl. 40/515; 29/428; 29/825

(57) ABSTRACT

A system to display a flag and a method of manufacturing the flag display system are described. The system includes an attachment member configured to affix the system to a structure horizontally, vertically, or at an angle in between. The system also includes a flag housing configured to house a flag, the flag housing being coupled to the attachment member, a roller member disposed in the flag housing, the flag being disposed to roll onto and off of the roller member to be stored or displayed, respectively, and a guide member coupled to the roller member at a first end in the flag housing, the guide member being configured to maintain alignment between the flag and the roller member when the flag is rolled onto and off of the roller member.

### CROSS-REFERENCE TO RELATED APPLICATION

This application claims priority to Provisional Patent Application Ser. No.: 61/560,027 filed Nov. 15, 2011, the disclosure of which is incorporated by reference herein in its entirety.

### BACKGROUND OF THE INVENTION

The subject matter disclosed herein relates to displaying a flag.

Individuals and businesses display flags on a regular basis. Typically, flags are displayed on vertical masts or ones that make a forty-five degree angle with a vertical structure, such as an exterior wall of a home. When flags are left outdoors during weather conditions such as rain, heavy winds, and dust storms, the condition of the flag material can deteriorate. Preventing this deterioration has required frequent and inconvenient removal and resetting. Thus, a convenient and effective way to display a flag over a long period of time would be appreciated.

### BRIEF DESCRIPTION OF THE INVENTION

According to an aspect, a system to display a flag includes an attachment member configured to affix the system to a structure horizontally, vertically, or at an angle in between; a flag housing configured to house a flag, the flag housing being coupled to the attachment member; a roller member disposed in the flag housing, the flag being disposed to roll onto and off of the roller member to be stored or displayed, respectively; and a guide member coupled to the roller member at a first end in the flag housing, the guide member being configured to maintain alignment between the flag and the roller member when the flag is rolled onto and off of the roller member.

According to another aspect, a method to manufacture a flag display system includes coupling a flag housing to an attachment member, the attachment member including an attachment portion to affix the flag display system to a structure horizontally, vertically, or at an angle therebetween; disposing a roller member in the flag housing, the roller member configured to roll a flag into and out of the flag housing; and positioning a guide member coupled to the roller member at a first end of the flag housing, the guide member including a notched portion and the attachment portion being disposed at an opposite end of the attachment member from the first end.

These and other advantages and features will become more apparent from the following description taken in conjunction with the drawings.

### BRIEF DESCRIPTION OF THE DRAWING

The subject matter, which is regarded as the invention, is particularly pointed out and distinctly claimed in the claims at the conclusion of the specification. The foregoing and other features, and advantages of the invention are apparent from the following detailed description taken in conjunction with the accompanying drawings in which:

FIG. 1 depicts a system to display a flag according to an embodiment of the invention;

FIG. 2 is a block diagram of components in the flag housing shown in FIG. 1 according to several embodiments;

FIG. 3 illustrates details of the guide mechanism shown at FIG. 2 according to an embodiment; and

FIG. 4 depicts a flag according to an embodiment.

The detailed description explains embodiments of the invention, together with advantages and features, by way of example with reference to the drawings.

### DETAILED DESCRIPTION OF THE INVENTION

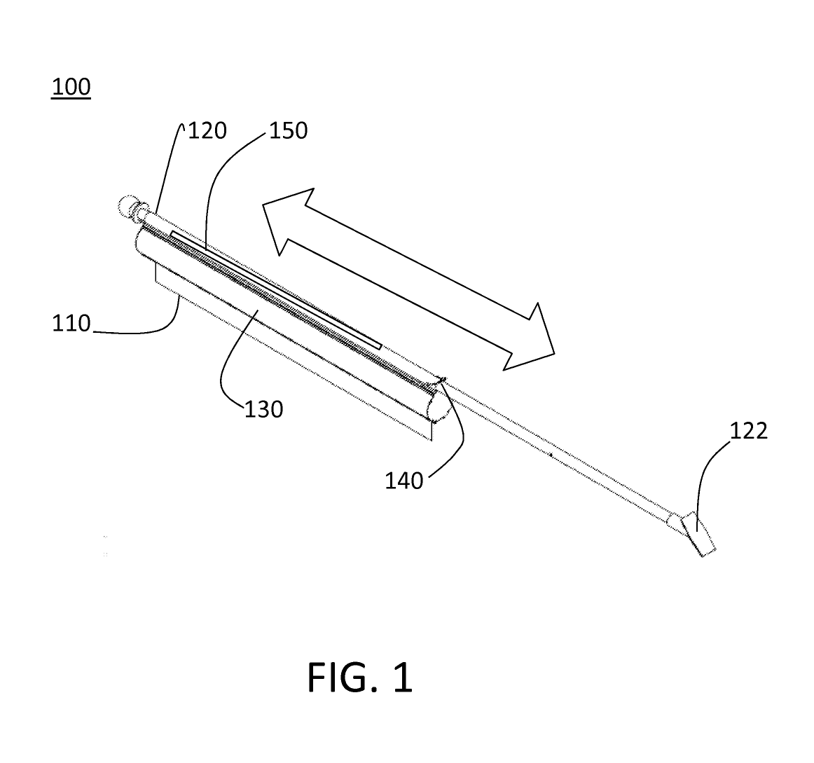

FIG. 1 depicts a system 100 to display a flag 110 according to an embodiment of the invention. The attachment member 120 affixes the system 100 to a structure (not shown) such as, for example, a building or a ground mount. The attachment portion 122 of the attachment member 120 may pivot in various embodiments to allow attachment of the system 100 at various angles against the structure. For example, a typical arrangement is one in which the system 100 is attached at the attachment portion 122 such that the flag 110 is flying at a forty-five degree angle. The attachment member 120 in the embodiment of FIG. 1 is essentially a rod with a base (attachment portion 122) that serves as the point at which the attachment member 120 is affixed to the structure. Exemplary types of fasteners to affix the attachment member 120 to a building or other structure include screws, nails, and adhesives. The attachment member 120 is coupled to a flag housing 130 that houses the flag 110.

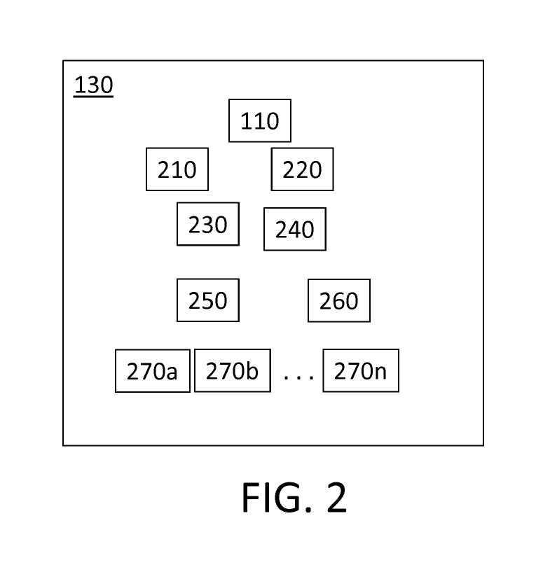

The flag housing 130 is configured to move along the axial span of the attachment member 120 as indicated by the arrows. The movement may be achieved manually through adjustment of a holding member 140. The holding member 140 may be, for example, a u-bolt that can be loosened to allow movement of the flag housing 130 and then re-tightened. In alternate embodiments, electronic control may be employed to move the flag housing 130 along the axial span of the attachment member 120. This electronically controlled movement may be achieved through a push of a button by an operator or via a remote instruction in various embodiments. By the various embodiments of the holding member 140, the flag 110 may be flown at half-mast (i.e., flag housing 130 is half way between the attachment portion 122 and the other end of the attachment member 120, referred to herein as the top end of the system 100) or at full-mast (i.e., flag housing 130 at the top end of the system 100) or in some other position determined by the user. One or more lights 150 may be mounted on the attachment member 120 and will be discussed further with reference to the light controller 250 (FIG. 2) below.

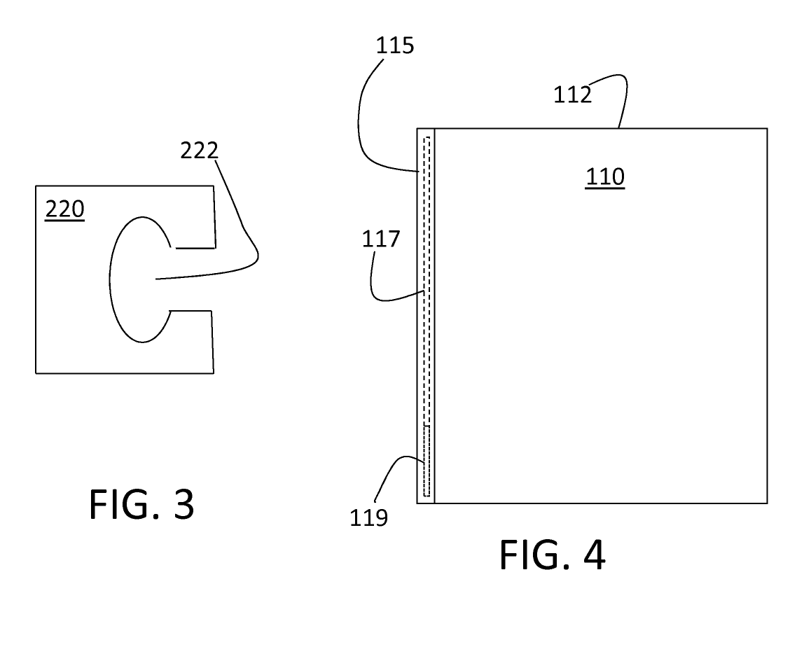

FIG. 2 is a block diagram of components in the flag housing 130 shown in FIG. 1 according to several embodiments. The flag housing 130, in addition to housing the flag 110, also houses a roller member 210, guide member 220, controller 230, antenna 240, light controller 250, sound system controller 260, and one or more sensors 270. The roller member 210 facilitates rolling of the flag 110 up into the flag housing 130 and out (unfurled) of the flag housing 130. The roller member 210 is a rod, for example. The length of the roller member 210 (along the axial span of the attachment member 120) may be greater than the width of the flag 110 (the portion of the flag parallel with the axial span of the attachment member 120) such that the flag 110 rolls onto the roller member 210. The guide member 220 is positioned at an end of the roller member 210 closest to the top end of the system 100 to keep the flag 110 in alignment with the roller member 210 when the flag 110 is rolled into and out of the flag housing 130. The guide member 220 is detailed with reference to FIG. 3 below.

The controller 230 may include one or more processors and one or more memory devices. The controller 230 is in communication with an antenna 240 to receive remote instructions. The remote instructions may include instructions to roll the flag 110 into or out of the flag housing 130. The remote instructions may also include instructions to move the flag housing 130 along the axial span of the attachment member 120 in some embodiments, as noted above, in conjunction with the holding member 140. The light controller 250 controls the lights 150 on the outside of the flag housing 130. The sound system controller 260 controls sound output from the flag housing 130 and includes one or more speakers. One or both of the light controller 250 and the sound system controller 260 may be integrated with the controller 230 rather than having separate processors (one or more) or memory devices (one or more). One or both of the light controller 250 and sound system controller 260 may include an additional antenna or may be in communication with the antenna 240 in order to receive remote instructions. The antenna 240 may be, for example, an RF antenna. Each of the controllers 230, 250, 260 may operate based not only on remote instructions but also on sensor output from one or more of the sensors 270a-270n. The sensors 270 may sense one or more of the following: wind, rain, and light. Thus, for example, when rain is detected by a rain sensor 270 or high wind is detected by the wind detector 270, the controller 230 may roll up the flag 110 to prevent weathering and damage. As another example, based on various sensor 270 outputs and remote instructions, the flag may be unfurled and flown at half-mast with the lights on and with music playing. As yet another example, the United States flag may be displayed twenty-four hours a day if it is properly illuminated during the hours of darkness. Thus, the lights 150 may be controlled (by the controller 260) to turn on and illuminate the flag when a sensor 270 (a light sensor) detects the absence of light. The controllers 230, 250, 260 and sensors 270 may be powered by batteries, solar power, or by a combination of power sources. For example, a batter pack may be included in the flag housing 130. More than one power source may be used, as well.

FIG. 3 illustrates details of the guide member 220 shown at FIG. 2 according to an embodiment. The guide member 220, coupled to the roller member 210 at the top end of the system 100 has a notched portion 222 that works to hold the flag 110 in place when it is being rolled into and out of the flag housing 130. The need for the guide member 220 is clear when two different scenarios are considered. First, when the attachment member 120 is affixed to a structure at ninety degrees (the attachment member 120 is perpendicular to a wall such that the flag 110 hangs straight down), the flag 110 may roll up and down on the roller member 210 without issue. That is, a flag 110 that is hanging straight down is likely to roll onto and off of the roller member 210 without skewing from a given alignment with the roller mechanism 210. However, when the attachment member 120 is then affixed to a structure at forty-five degrees, the flag 110 is no longer hanging straight down. At such an angle, when the flag 110 rolls onto and off of the roller member 210, the flag is likely to lose its alignment with the roller member 210 because flag 110 material is bunching up at the top end of the system 100. This situation is prevented by the guide member 220. By maintaining the seam 115 (FIG. 4) of the flag 110 that contacts the roller member 210 at the top end of the system 100 in the notched portion 222, the flag 110 material at the top end of the system 100 is prevented from bunching and, thereby, losing alignment with the roller member 210.

FIG. 4 depicts a flag 110 according to an embodiment. The seam 115 of the flag 110 that is positioned closest to the top end of the system 100 includes a guide 117 and one or more weights 119. The guide 117 may be, for example, a metal wire with thickness sufficient to keep the seam 115 of the flag 110 in the notched portion 222 (FIG. 3) of the guide member 220. The one or more weights 119 work in conjunction with the notched portion 222 of the guide member 220 to keep the flag 110 in alignment with the roller member 210. The seam 115 with the guide 117 and one or more weights 119 may be integral with the flag 110 or, in alternate embodiments, may be configured as an attachment to any regular flag to form a flag 110 (as shown in FIG. 4). For example, the seam 115 with the guide 117 and one or more weights 119 within it may be configured to be attached via a fabric hook-and-loop fastener, adhesive, pins, or some other method to any flag to be used with the system 100. In the arrangement shown in FIG. 4, the entire span of the top edge 112 of the flag 110 rolls onto the roller mechanism 210 (rod) while the seam 115 is maintained in the notched portion 222 of the guide member 220 that is coupled to the roller member 210 in the flag housing 130.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A system to display a flag, the system comprising:
an attachment member configured to affix the system to a structure horizontally, vertically, or at an angle in between;
a flag housing configured to house a flag, the flag housing being coupled to the attachment member;
a roller member disposed in the flag housing, the flag being disposed to roll onto and off of the roller member to be stored or displayed, respectively; and
a guide member coupled to the roller member at a first end in the flag housing, the guide member being configured to maintain alignment between the flag and the roller member when the flag is rolled onto and off of the roller member.

2. The system according to claim 1, wherein the flag housing has a cylindrical shape with an opening to facilitate the flag movement into and out of the flag housing onto and off of a rod-shaped roller member, respectively.

3. The system according to claim 1, wherein the flag includes a seam portion along a side of the flag associated with the first end, and the guide member includes a notched portion configured to maintain the seam portion in alignment with the roller member.

4. The system according to claim 3, wherein the seam portion includes a guide and one or more weights.

5. The system according to claim 1, further comprising a holding member configured to hold the flag housing at a first axial location of the attachment member.

6. The system according to claim 5, wherein the flag housing may be moved to a second axial location of the attachment member by controlling the holding member.

7. The system according to claim 6, wherein the flag housing is positioned at half-mast by controlling the holding member.

8. The system according to claim 1, further comprising a controller configured to control the roller member to roll the flag into and out of the flag housing.

9. The system according to claim 8, wherein the controller is coupled to an antenna to receive remote instructions.

10. The system according to claim 8, further comprising one or more sensors, wherein the controller controls the roller member based on output from the one or more sensors.

11. The system according to claim 1, further comprising at least one of one or more lights affixed to the system or an audio output coupled to the system.

12. A method to manufacture a flag display system, the method comprising:
coupling a flag housing to an attachment member, the attachment member including an attachment portion to affix the flag display system to a structure horizontally, vertically, or at an angle therebetween;
disposing a roller member in the flag housing, the roller member configured to roll a flag into and out of the flag housing; and
positioning a guide member coupled to the roller member at a first end of the flag housing, the guide member including a notched portion and the attachment portion being disposed at an opposite end of the attachment member from the first end.

13. The method according to claim 12, further comprising, disposing a holding member to hold the flag housing at a position on the attachment member.

14. The method according to claim 13, wherein the disposing the holding member includes configuring the holding member to be loosened and repositioned to facilitate movement of the flag housing along the axial span of the attachment member.

15. The method according to claim 12, further comprising coupling a controller to the roller member.

16. The method according to claim 15, further comprising coupling an antenna to the controller to receive a remote instruction, wherein the controller is configured to roll the roller member based on the remote instruction.

17. The method according to claim 15, further comprising coupling one or more sensors to the controller, wherein the controller is configured to roll the roller member based on an output of the one or more sensors.

18. The method according to claim 12, further comprising coupling at least one of one or more lights or an audio system to the attachment member.

19. The method according to claim 12, further comprising manufacturing a flag seam with a guide and one or more weights in the flag seam, the flag seam configured to attach to a side of a flag and be maintained in alignment with the roller member by the guide member.
